(19) United States
(12) Patent Application Publication
(10) Pub. No.: US 2024/0387209 A1
(43) Pub. Date: Nov. 21, 2024

(54) SUBSTRATE PROCESSING METHOD, METHOD OF MANUFACTURING SEMICONDUCTOR DEVICE, SUBSTRATE PROCESSING APPARATUS AND NON-TRANSITORY COMPUTER- READABLE RECORDING MEDIUM

(71) Applicant: KOKUSAI ELECTRIC COPRORATION, Tokyo (JP)

(72) Inventors: Masaru KADOSHIMA, Toyama-shi (JP); Kaoru Yamamoto, Toyama-shi (JP); Toshiyuki Kikuchi, Toyama-shi (JP); Naofumi Ohashi, Toyama-shi (JP)

(73) Assignee: KOKUSAI ELECTRIC CORPORATION, Tokyo (JP)

(21) Appl. No.: 18/615,733

(22) Filed: Mar. 25, 2024

(30) Foreign Application Priority Data
May 19, 2023 (JP) 2023-082673

(51) Int. Cl. H01L 21/67; C23C 16/455; C23C 16/52; H01J 37/32; H01L 21/66

(52) U.S. Cl. CPC H01L 21/67248; C23C 16/45544; C23C 16/52; H01J 37/32449; H01L 22/12; H01J 2237/332

(57) ABSTRACT

There is provided a technique capable of suppressing a variation within a substrate processing. There is provided a technique that includes performing a cycle a plurality of times, the cycle including: (a) storing a first process gas in a storage; (b) supplying the first process gas from the storage at a first temperature to a substrate after (a) to change a temperature of the storage to a second temperature lower than the first temperature; and (c) changing the temperature of the storage after supplying the first process gas to a third temperature after (b), wherein (a), (b) and (c) are sequentially performed in the cycle, and wherein the third temperature is kept within a predetermined temperature range while the cycle is performed the plurality of times.

### CROSS-REFERENCE TO RELATED PATENT APPLICATION

This non-provisional U.S. patent application is based on and claims priority under 35 U.S.C. § 119 of Japanese Patent Application No. 2023-082673, filed on May 19, 2023, in the Japanese Patent Office, the entire contents of which are hereby incorporated by reference.

### BACKGROUND

### 1. Field

The present disclosure relates to a substrate processing method, a method of manufacturing a semiconductor device, a substrate processing apparatus and a non-transitory computer-readable recording medium.

### 2. Related Art

According to some related arts, a substrate may be processed by performing a step of storing a process gas in a storage and a step of supplying the process gas stored in the storage to the substrate. The steps described above may be performed a predetermined number of times.

### SUMMARY

According to the present disclosure, there is provided a technique capable of suppressing a variation with a substrate processing.

According to an aspect of the present disclosure, there is provided a technique that includes: performing a cycle a plurality of times, the cycle including: (a) storing a first process gas in a storage; (b) supplying the first process gas from the storage at a first temperature to a substrate after (a) to change a temperature of the storage to a second temperature lower than the first temperature; and (c) changing the temperature of the storage after supplying the first process gas to a third temperature after (b), wherein (a), (b) and (c) are sequentially performed in the cycle, and wherein the third temperature is kept within a predetermined temperature range while the cycle is performed the plurality of times.

### BRIEF DESCRIPTION OF THE DRAWINGS

FIG. 1 is a diagram schematically illustrating a vertical cross-section of a vertical type process furnace of a substrate processing apparatus preferably used in one or more embodiments of the present disclosure.

FIG. 2 is a diagram schematically illustrating a first gas supplier of the substrate processing apparatus preferably used in the embodiments of the present disclosure.

FIG. 3 is a block diagram schematically illustrating an exemplary configuration of a controller and related components of the substrate processing apparatus shown in FIG. 1.

FIG. 4 is a flow chart schematically illustrating an example of a substrate processing using the substrate processing apparatus shown in FIG. 1.

FIG. 5 is a diagram schematically illustrating a relationship between a temperature of a tank and a time in a comparative example in which a temperature adjusting step of a first process gas supply step shown in FIG. 4 is not included.

FIG. 6 is a diagram schematically illustrating a relationship between the temperature of the tank and the time in the first process gas supply step shown in FIG. 4.

FIG. 7A is a flow chart schematically illustrating a first example of sub-steps of a storage step shown in FIG. 4.

FIG. 7B is a flow chart schematically illustrating a second example of sub-steps of the storage step shown in FIG. 4.

FIG. 7C is a flow chart schematically illustrating a third example of sub-steps of the storage step shown in FIG. 4.

FIG. 7D is a flow chart schematically illustrating a fourth example of sub-steps of the storage step shown in FIG. 4.

FIG. 8 is a flow chart schematically illustrating another example of sub-steps of the first process gas supply step shown in FIG. 4.

### DETAILED DESCRIPTION

### Embodiments of Present Disclosure

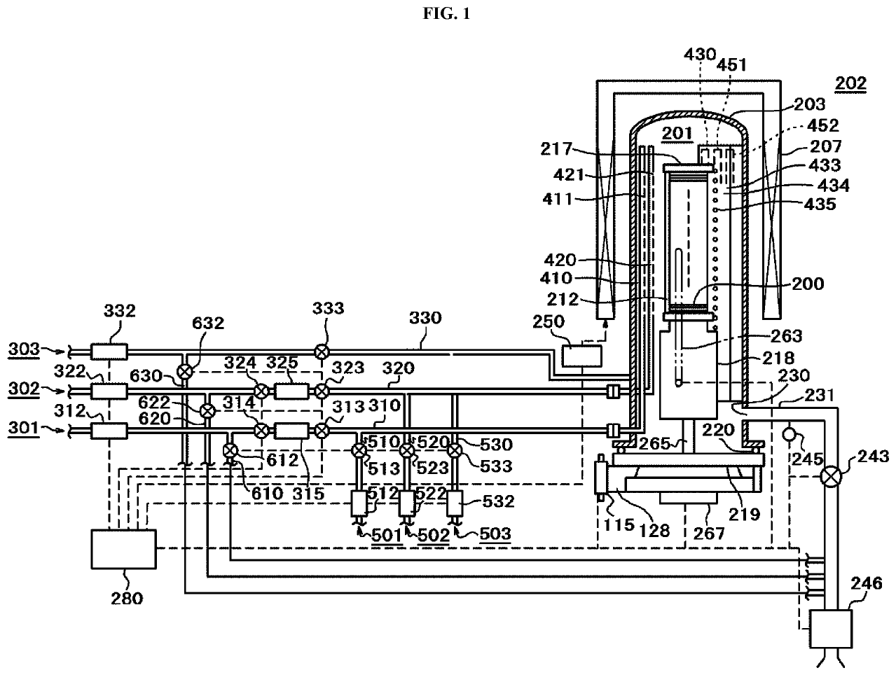

Hereinafter, one or more embodiments (also simply referred to as “embodiments”) according to the technique of the present disclosure will be described mainly with reference to FIGS. 1 through 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or similar reference numerals represent the same or similar components in the drawings. Thus, each component is described with reference to the drawing in which it first appears, and redundant descriptions related thereto will be omitted unless particularly necessary. Further, the number of each component described in the present specification is not limited to one, and the number of each component described in the present specification may be two or more unless otherwise specified in the present specification.

### (1) Configuration of Substrate Processing Apparatus

A substrate processing apparatus according to the present embodiments includes a vertical type process furnace (hereinafter, simply referred to as a “process furnace”) 202. The process furnace 202 includes a reaction tube 203. For example, the reaction tube 203 is made of a heat resistant material such as quartz (SiO₂) and silicon carbide (SiC). A heater 207 serving as a heating apparatus (heating structure) is provided outside the reaction tube 203 in a manner concentric with the reaction tube 203. A heating power supply 250 is connected to the heater 207. A seal cap 219 serving as a furnace opening lid is provided under the reaction tube 203. An O-ring 220 serving as a seal is provided between a lower end of the reaction tube 203 and an upper surface of the seal cap 219. For example, the seal cap 219 is made of a metal such as stainless steel (SUS), and is capable of airtightly closing (or sealing) a lower end opening of the reaction tube 203. A process chamber 201 is defined by an inside of the reaction tube 203. The process chamber 201 is configured to accommodate a plurality of wafers including a wafer 200 serving as a substrate. Hereinafter, the plurality of wafers including the wafer 200 may also be simply referred to as “wafers 200”.

A boat support 218 configured to support a boat 217 serving as a substrate retainer is provided on the seal cap 219. The boat 217 includes a bottom plate fixed on the boat support 218 and a top plate disposed above the bottom plate. A plurality of support columns is provided between the bottom plate and the top plate so as to connect the bottom plate and the top plate. The wafers 200 are stacked (loaded) in a horizontal orientation on the plurality of support columns of the boat 217 in a multistage manner with a predetermined interval therebetween and with their centers aligned with one another. A stacking direction of the wafers 200 is equal to an axial direction of the reaction tube 203. For example, each of the boat support 218, the bottom plate, the top plate and the plurality of support columns is made of the heat resistant material described above. A rotator (which is a rotating structure) 267 is provided at the seal cap 219 opposite to the process chamber 201. A rotating shaft 265 of the rotator 267 is connected to the boat support 218 through the seal cap 219. As the rotator 267 rotates the rotating shaft 265, the boat 217 and the wafers 200 supported by the boat 217 are rotated. The seal cap 219 can be elevated or lowered in the vertical direction by a boat elevator 115. The boat elevator 115 serves as a transfer device configured to transfer the boat 217 and the wafers 200 supported by the boat 217 into or out of the process chamber 201.

Nozzles 410, 420 and 430 are provided in the process chamber 201 to penetrate a lower side wall of the reaction tube 203. Gas supply pipes 310, 320 and 330 are connected to the nozzles 410, 420 and 430, respectively.

Mass flow controllers (MFCs) 312 and 322, valves 314 and 324, tanks 315 and 325 and valves 313 and 323 are sequentially installed at the gas supply pipes 310 and 320, respectively, in this order from upstream sides to downstream sides of the gas supply pipes 310 and 320 in a gas flow direction. In other words, the valves 314 and 324 are provided on a primary side of the tanks 315 and 325, and the valves 313 and 323 are provided on a secondary side of the tanks 315 and 325. Each of the MFCs 312 and 322 may also be referred to as a “flow rate controller”. Each of the valves 314 and 324 serves as an opening/closing valve, and the valves 314 and 324 may be collectively or individually referred to as a “first valve”. The tanks 315 and 325 may be collectively or individually referred to as a “storage” which is a storage structure. Each of the valves 313 and 323 serves as an opening/closing valve, and the valves 313 and 323 may be collectively or individually referred to as a “second valve”. One or both of the first valve and the second valve may be considered as a gas controller capable of controlling a storage of a first process gas in the storage and a supply of the first process gas from the storage to the wafers 200 in the process chamber 201. Vaporizers 317 and 327 serving as a part of a process gas supplier (which is a process gas supply structure or a process gas supply system) are connected to the gas supply pipes 310 and 320, respectively. Heat exchangers 318 and 328 serving as a preheating structure (preliminary heater) are provided at downstream sides of the MFCs 312 and 322, respectively. Alternatively, the heat exchangers 318 and 328 may be provided at upstream sides of the MFCs 312 and 322, respectively.

Vent gas pipes 610 and 620 are connected to the gas supply pipes 310 and 320, respectively, between the MFCs 312 and 322 and the valves 314 and 324 of the gas supply pipes 310 and 320. The vent gas pipes 610 and 620 are connected to a downstream side of an APC valve 243 of an exhaust pipe 231 described later. Valves 612 and 622 are provided at the vent gas pipes 610 and 620, respectively. Gas supply pipes 510 and 520 through which an inert gas is supplied are connected to the gas supply pipes 310 and 320, respectively, at downstream sides of the valves 313 and 323 of the gas supply pipes 310 and 320. MFCs 512 and 522 and valves 513 and 523 are sequentially installed at the gas supply pipes 510 and 520, respectively, in this order from upstream sides to downstream sides of the gas supply pipes 510 and 520 in the gas flow direction.

Downstream ends of the gas supply pipes 310 and 320 are connected to upstream ends of the nozzles 410 and 420, respectively. Each of the nozzles 410 and 420 is installed in an annular space between an inner wall of the reaction tube 203 and the wafers 200 accommodated in the process chamber 201, and extends upward from a lower portion of the inner wall of the reaction tube 203 to an upper portion of the inner wall of the reaction tube 203 along the stacking direction of the wafers 200. A plurality of gas supply ports 411 and a plurality of gas supply ports 421 are provided on side portions (side surfaces) of the nozzles 410 and 420 at positions respectively corresponding to the wafers 200.

Each of tanks 315 and 325 may be constituted by a component such as a gas tank or a spiral pipe whose gas capacity is greater than that of a normal pipe. By opening and closing the valves 314 and 324 provided on upstream sides of the tanks 315 and 325 and the valves 313 and 323 provided on downstream sides of the tanks 315 and 325, a gas supplied through the gas supply pipes 310 and 320 can be temporarily filled (stored) in the tanks 315 and 325, and the gas temporarily stored in the tanks 315 and 325 can be supplied into the process chamber 201. It is preferable that a conductance between the tanks 315 and 325 and the process chamber 201 is set to 1.5×10⁻³ m³/s or more, for example. When a volume of the reaction tube 203 is 100 liters, it is preferable that a volume of the tank 315 is set to a predetermined volume within a range from 100 cc to 300 cc, for example.

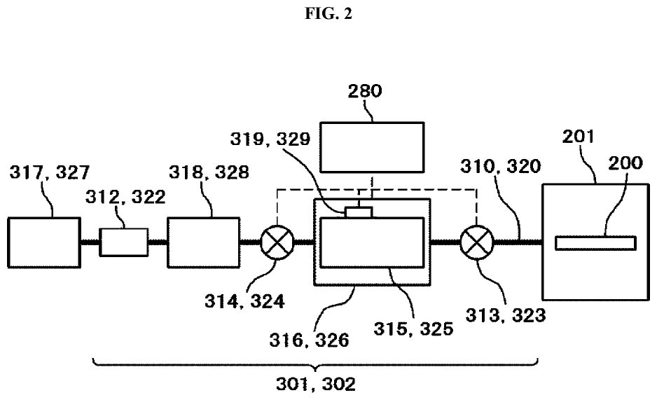

As shown in FIG. 2, the tanks 315 and 325 are provided with tank heaters 316 and 326 serving as a temperature regulator (which is a temperature adjuster, a temperature adjusting structure or a heater) and thermocouples 319 and 329 serving as a temperature measurer (which is a temperature measuring structure), respectively. Based on temperature information detected by the thermocouples 319 and 329, an electric power supplied to the tank heaters 316 and 326 from a power source (not shown) can be adjusted. Thereby, it is possible to control temperatures of the tanks 315 and 325 to a desired temperature. In other words, outputs of the tank heaters 316 and 326 are feedback-controlled with respect to the temperatures of the tanks 315 and 325.

By closing the valves 313, 323, 612 and 622 and opening the valves 314 and 324, the gas whose flow rate is adjusted by the MFCs 312 and 322 may be temporarily stored in the tanks 315 and 325. By closing the valves 314 and 324 and opening the valves 313 and 323 after a predetermined amount of the gas is stored in the tanks 315 and 325 and inner pressures of the tanks 315 and 325 reach a predetermined pressure, the gas stored in each of the tanks 315 and 325 with a high pressure may be supplied into the process chamber 201 at once (in a short time) through the gas supply pipes 310 and 320 and the nozzles 410 and 420. When the gas is supplied into the process chamber 201, by opening the valves 513 and 523, the inert gas whose flow rate is adjusted by the MFCs 512 and 522 may also be supplied into the process chamber 201 through the gas supply pipes 310 and 320 and the nozzles 410 and 420.

Further, by closing the valves 314 and 324 and opening the valves 612 and 622, the gas whose flow rate is adjusted by the MFCs 312 and 322 may be bypassed without being supplied into the process chamber 201, and exhausted to the exhaust pipe 231 through the vent gas pipes 610 and 620. In addition, by closing the valves 313 and 323 and opening the valves 513 and 523, the inert gas whose flow rate is adjusted by the MFCs 512 and 522 may be supplied into the process chamber 201 through the gas supply pipes 310 and 320 and the nozzles 410 and 420 so as to purge an inner atmosphere of the process chamber 201.

The first process gas is supplied through the gas supply pipes 310 and 320 into the process chamber 201 via the MFCs 312 and 322, the valves 314 and 324, the tanks 315 and 325, the valves 313 and 323 and the nozzles 410 and 420.

The inert gas is supplied through the gas supply pipes 510 and 520 into the process chamber 201 via the MFCs 512 and 522, the valves 513 and 523, the gas supply pipes 310 and 320 and the nozzles 410 and 420.

First process gas suppliers (each of which is a first process gas supply structure or a first process gas supply system) 301 and 302 are constituted mainly by the gas supply pipes 310 and 320, the MFCs 312 and 322, the heat exchangers 318 and 328, the valves 314 and 324, the tanks 315 and 325, and the valves 313 and 323. The first process gas suppliers 301 and 302 may further include the vaporizers 317 and 327 and/or the nozzles 410 and 420. Further, first inert gas suppliers (each of which is a first inert gas supply structure or a first inert gas supply system) 501 and 502 are constituted mainly by the gas supply pipes 510 and 520, the MFCs 512 and 522 and the valves 513 and 523. The present embodiments will be described by way of an example in which the first process gas suppliers 301 and 302 is constituted by the structure 301 including the gas supply pipe 310, the MFC 312, the heat exchanger 318, the valve 314, the tank 315 and the valve 313 and the structure 302 including the gas supply pipe 320, the MFC 322, the heat exchanger 328, the valve 324, the tank 325 and the valve 323. However, the structure 301 alone may be provided or the structure 302 alone may be provided as the first process gas supplier.

An MFC 332 and a valve 333 are sequentially installed at the gas supply pipe 330 in this order from an upstream side to a downstream side of the gas supply pipe 330 in the gas flow direction. A vent gas pipe 630 is connected to the gas supply pipe 330 between the MFC 332 and the valve 333 of the gas supply pipe 330. The vent gas pipe 630 is connected to the downstream side of the APC valve 243 of the exhaust pipe 231 described later. A valve 632 is provided at the vent gas pipe 630. A gas supply pipe 530 through which the inert gas is supplied is connected to the gas supply pipe 330 at a downstream side of the valve 333 of the gas supply pipe 330. An MFC 532 and a valve 533 are sequentially installed at the gas supply pipe 530 in this order from an upstream side to a downstream side of the gas supply pipe 530 in the gas flow direction.

The gas supply pipe 330 is connected to the nozzle 430. The nozzle 430 is provided in a buffer chamber 433 serving as a gas dispersion space.

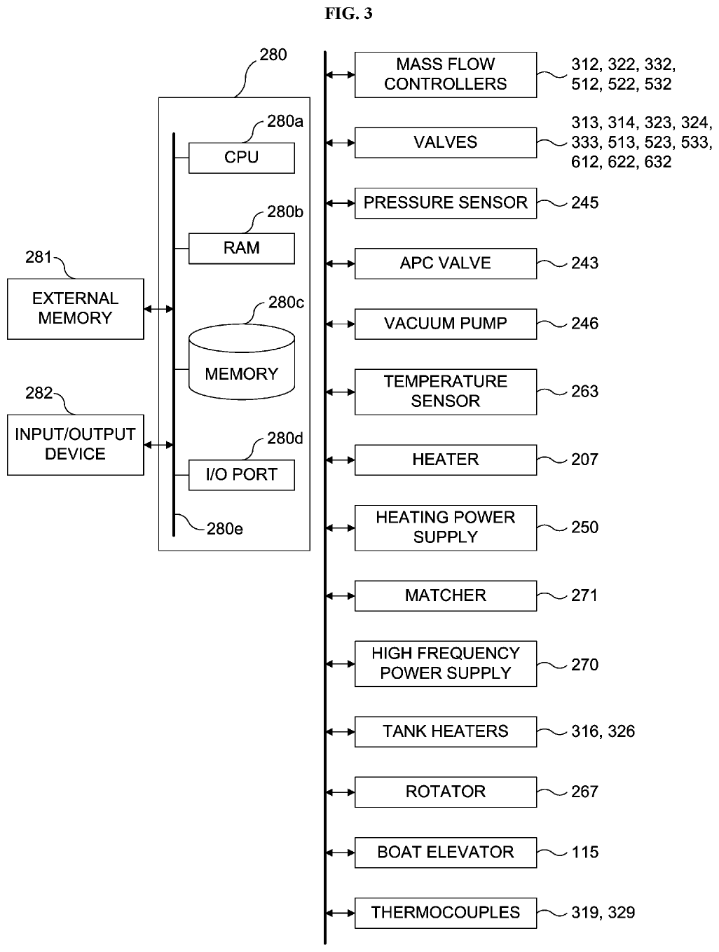

The buffer chamber 433 is defined by the inner wall of the reaction tube 203 and a buffer chamber wall 434. The buffer chamber wall 434 is installed in the annular space between the inner wall of the reaction tube 203 and the wafers 200 accommodated in the process chamber 201 in a portion extending from the lower portion to the upper portion of the inner wall of the reaction tube 203 along the stacking direction of the wafers 200. A plurality of gas supply ports 435 through which a gas is supplied are provided on a portion of the buffer chamber wall 434 adjacent to the wafers 200. The gas supply ports 435 are opened toward a central portion of the reaction tube 203. The gas supply ports 435 are arranged from a lower portion to an upper portion of the reaction tube 203. A pair of rod-shaped electrodes are provided in the buffer chamber 433 to which a high frequency power is applied from a high frequency power supply 270 (see FIG. 3) via a matcher (which is a matching structure) 271 (see FIG. 3).

The nozzle 430 is installed on one side of the buffer chamber 433, and extends upward from the lower portion of the inner wall of the reaction tube 203 to the upper portion of the inner wall of the reaction tube 203 along the stacking direction of the wafers 200. A plurality of gas supply ports 431 through which a gas is supplied are provided on a side surface of the nozzle 430. The gas supply ports 431 are opened toward a central portion of the buffer chamber 433. Similar to the gas supply ports 435 of the buffer chamber 433, the gas supply ports 431 are provided from the lower portion to the upper portion of the reaction tube 203.

By opening the valve 333, the gas whose flow rate is adjusted by the MFC 332 may be supplied into the process chamber 201 through the gas supply pipe 330, the nozzle 430 and the buffer chamber 433. When the gas is supplied into the process chamber 201, by opening the valve 533, the inert gas whose flow rate is adjusted by the MFC 532 may also be supplied into the process chamber 201 through the gas supply pipe 330, the nozzle 430 and the buffer chamber 433. In addition, by closing the valve 333 and opening the valve 632, the gas whose flow rate is adjusted by the MFC 332 may be bypassed without being supplied into the process chamber 201, and exhausted to the exhaust pipe 231 through the vent gas pipe 630. In addition, by closing the valve 333 and opening the valve 533, the inert gas whose flow rate is adjusted by the MFC 532 may be supplied into the process chamber 201 through the gas supply pipe 330, the nozzle 430 and the buffer chamber 433 so as to purge the inner atmosphere of the process chamber 201.

A second process gas whose chemical structure (molecular structure) is different from that of the first process gas is supplied through the gas supply pipe 330 into the process chamber 201 via the MFC 332, the valve 333, the nozzle 430 and the buffer chamber 433.

The inert gas is supplied through the gas supply pipe 530 into the process chamber 201 via the MFC 532, the valve 533, the gas supply pipe 330, the nozzle 430 and the buffer chamber 433.

A second process gas supplier (which is a second process gas supply structure or a second process gas supply system) 303 is constituted mainly by the gas supply pipe 330, the MFC 332 and the valve 333. The second process gas supplier 303 may further include the nozzle 430 and/or the buffer chamber 433. Further, a second inert gas supplier (which is a second inert gas supply structure or a second inert gas supply system) 503 is constituted mainly by the gas supply pipe 530, the MFC 532 and the valve 533.

An exhaust port 230 is provided at the lower portion of the reaction tube 203. The exhaust pipe 231 through which the inner atmosphere of the process chamber 201 is exhausted is connected to the exhaust port 230. A pressure sensor 245, the APC (Automatic Pressure Controller) valve 243 and a vacuum pump 246 are sequentially installed at the exhaust pipe 231 in this order from an upstream side to a downstream side of the exhaust pipe 231 in the gas flow direction. The pressure sensor 245 is configured to detect an inner pressure of the process chamber 201, and may also be referred to as a “pressure detector”. The APC valve 243 may also be referred to as a “pressure regulator” which is a pressure adjuster or a pressure adjusting structure. Further, the vacuum pump 246 may also be referred to as a “vacuum exhausting apparatus”. With the vacuum pump 246 in operation, the APC valve 243 may be opened or closed to perform a vacuum-exhaust of the process chamber 201 or stop the vacuum-exhaust. Further, with the vacuum pump 246 in operation, an opening degree of the APC valve 243 may be adjusted in order to adjust the inner pressure of the process chamber 201. An exhauster (which is an exhaust structure or an exhaust system) is constituted mainly by the exhaust pipe 231, the APC valve 243 and the pressure sensor 245. The exhauster may further include the vacuum pump 246.

A temperature sensor 263 serving as a temperature detector is provided in the reaction tube 203. The electric power supplied to the heater 207 from the heating power supply 250 is adjusted based on temperature information detected by the temperature sensor 263 such that a temperature distribution of an inner temperature of the process chamber 201 is adjusted to a desired temperature distribution.

As shown in FIG. 3, a controller 280 serving as a control structure is configured as a computer including a CPU (Central Processing Unit) 280a, a RAM (Random Access Memory) 280b, a memory 280c and an I/O port 280d. The RAM 280b, the memory 280c and the I/O port 280d may exchange data with the CPU 280a through an internal bus 280e. For example, an input/output device 282 constituted by a component such as a touch panel (not shown) may be connected to the controller 280.

The memory 280c may be embodied by a component such as a flash memory and a hard disk drive (HDD). For example, a control program configured to control operations of the substrate processing apparatus and a process recipe containing information on sequences and conditions of a substrate processing described later may be readably stored in the memory 280c. The process recipe is obtained by combining steps of the substrate processing described later such that the controller 280 can execute the steps to acquire a predetermined result, and functions as a program. Hereinafter, the process recipe and the control program may be collectively referred to as a “program”. Further, the process recipe may also be simply referred to as a “recipe”. Thus, in the present specification, the term “program” may refer to the recipe alone, may refer to the control program alone, or may refer to both of the recipe and the control program. The RAM 280b functions as a memory area (work area) where a program or data read by the CPU 280a is temporarily stored.

The I/O port 280d is connected to components such as the MFCs 312, 322, 332, 512, 522 and 532, the valves 313, 314, 323, 324, 333, 513, 523, 533, 612, 622 and 632, the pressure sensor 245, the APC valve 243, the vacuum pump 246, the heater 207, the heating power supply 250, the temperature sensor 263, the high frequency power supply 270, the matcher 271, the rotator 267, the boat elevator 115, the tank heaters 316 and 326 and the thermocouples 319 and 329.

The CPU 280a is configured to read the control program from the memory 280c and execute the read control program. Furthermore, the CPU 280a is configured to read a recipe such as the process recipe from the memory 280c in accordance with an operation command inputted from the input/output device 282. In accordance with the contents of the read recipe, the CPU 280a may be configured to control various operations such as flow rate adjusting operations for various gases by the MFCs 312, 322, 332, 512, 522 and 532 and opening/closing operations of the valves 313, 314, 323, 324, 333, 513, 523, 533, 612, 622 and 632. Further, the CPU 280a may be configured to control various operations such as an opening/closing operation of the APC valve 243, a pressure adjusting operation by the APC valve 243 based on the pressure sensor 245 and an operation of starting and stopping the vacuum pump 246. Further, the CPU 280a may be configured to control various operations such as a temperature adjusting operation of the heater 207 (or an output adjusting operation of the heating power supply 250) based on the temperature sensor 263, an operation of supplying the electric power by the high frequency power supply 270 and an impedance adjusting operation by the matcher 271. Further, the CPU 280a may be configured to control various operations such as an operation of adjusting a rotation and a rotation speed of the boat 217 by the rotator 267, an elevating and lowering operation of the boat 217 by the boat elevator 115 and an operation of the tank heaters 316 and 326 based on the thermocouples 319 and 329.

The controller 280 may be embodied by installing the above-described program stored in an external memory 281 into a computer. For example, the external memory 281 may include a magnetic disk such as a hard disk drive (HDD), an optical disk such as a CD, a magneto-optical disk such as an MO, and a semiconductor memory such as a USB memory. The memory 280c or the external memory 281 may be embodied by a non-transitory computer readable recording medium. Hereafter, the memory 280c and the external memory 281 may be collectively or individually referred to as a “recording medium”. Thus, in the present specification, the term “recording medium” may refer to the memory 280c alone, may refer to the external memory 281 alone, or may refer to both of the memory 280c and the external memory 281. Instead of the external memory 281, a communication interface such as the Internet and a dedicated line may be used for providing the program to the computer.

### (2) Substrate Processing

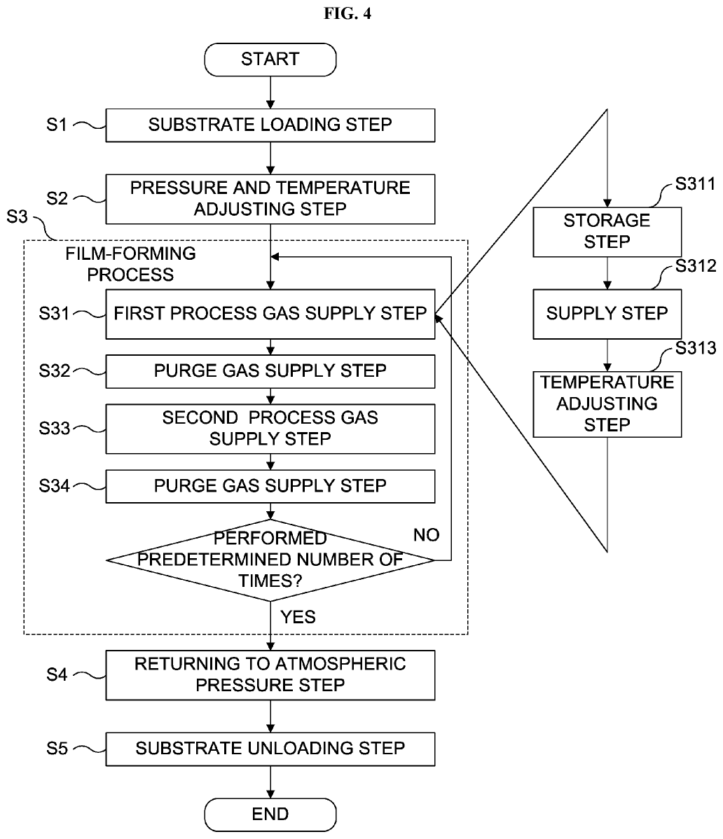

Hereinafter, an exemplary sequence of the substrate processing (that is, an exemplary sequence of a film forming process) of forming a film on the wafer 200, which is a part of a manufacturing process of a semiconductor device, will be described with reference to FIG. 4. The exemplary sequence of the film forming process is performed by using the substrate processing apparatus described above. Hereinafter, the operations of the components constituting the substrate processing apparatus are controlled by the controller 280.

In the present specification, the term “wafer” may refer to “a wafer itself” or may refer to “a wafer and a stacked structure (aggregated structure) of a predetermined layer (or layers) or a film (or films) formed on a surface of the wafer”. In addition, “a surface of a wafer” may refer to “a surface of a wafer itself” or may refer to “a surface of a predetermined layer (or layers) or a film (or films) formed on a wafer”. Thus, in the present specification, “forming a predetermined layer (or a film) on a wafer” may refer to “forming a predetermined layer (or a film) on a surface of a wafer itself” or may refer to “forming a predetermined layer (or a film) on a surface of another layer or another film formed on the wafer”. In the present specification, the terms “substrate” and “wafer” may be used as substantially the same meaning. That is, the term “substrate” may be substituted by “wafer” and vice versa.

### <Substrate Loading Step: S1>

After the wafers 200 are transferred (or charged) into the boat 217 (wafer charging step), the lower end opening of the reaction tube 203 is opened. Thereafter, the boat 217 charged with the wafers 200 is elevated by the boat elevator 115 and loaded (transferred) into the process chamber 201 (boat loading step). As shown in FIG. 1, with the boat 217 loaded, the seal cap 219 hermetically seals (closes) the lower end opening of the reaction tube 203 via the O-ring 220.

### <Pressure and Temperature Adjusting Step: S2>

The vacuum pump 246 exhausts (vacuum-exhausts) the inner atmosphere of the process chamber 201 such that the inner pressure of the process chamber 201 reaches and is maintained at a desired pressure (pressure adjusting step). In addition, the heater 207 heats the process chamber 201 such that the inner temperature of the process chamber 201 reaches and is maintained at a desired temperature (temperature adjusting step). In the present step, the wafers 200 are rotated by the rotator 267 (rotating step). The vacuum pump 246 continuously exhausts the inner atmosphere of the process chamber 201, the heater 207 continuously heats the process chamber 201, and the rotator 267 continuously rotates the wafers 200 at least until a processing of the wafer 200 is completed.

### <Film Forming Process: S3>

Thereafter, the film forming process S3 is performed by sequentially performing a first process gas supply step S31, a purge gas supply step S32, a second process gas supply step S33 and a purge gas supply step S34.

### <First Process Gas Supply Step: S31>

For example, the first process gas supply step S31 is performed by sequentially performing a storage step S311, a supply step S312 and a temperature adjusting step S313.

### <Storage Step: S311>

By opening the valves 314 and 324 with the valves 313, 323, 612 and 622 closed, the first process gas whose flow rate is adjusted by the MFCs 312 and 322 is filled (stored) into the tanks 315 and 325. For example, the tanks 315 and 325 are filled with the first process gas such that the inner pressures of the tanks 315 and 325 reach and are maintained at 20,000 Pa or higher. For example, an amount of the first process gas filled in each of the tanks 315 and 325 is set to an amount within a range from 100 cc to 250 cc. In the present specification, a notation of a numerical range such as “from 100 cc to 250 cc” means that a lower limit and an upper limit are included in the numerical range. Therefore, for example, a numerical range “from 100 cc to 250 cc” means a range equal to or more than 100 cc and equal to or less than 250 cc. The same also applies to other numerical ranges described in the present specification. When each of the tanks 315 and 325 is filled with the first process gas of a predetermined pressure and a predetermined amount, the valves 314 and 324 are closed. As a result, the first process gas is stored in the tanks 315 and 325.

### <Supply Step: S312>

While the tanks 315 and 325 are filled with the first process gas, the inner atmosphere of the process chamber 201 is exhausted such that the inner pressure of the process chamber 201 is adjusted to a predetermined pressure of 20 Pa or less, for example. After filling the tanks 315 and 325 with the first process gas and exhausting the inner atmosphere of the process chamber 201, the APC valve 243 is closed to close the exhauster, and the valves 313 and 323 are opened. Thereby, it is possible to supply the first process gas stored in the tanks 315 and 325 with a high pressure into the process chamber 201 at once. For example, the inner pressure of the process chamber 201 increases rapidly and reaches a pressure within a range from 800 Pa to 1,200 Pa. Thereafter, with the first process gas is confined in the process chamber 201, the wafers 200 are exposed to an atmosphere of the first process gas for a predetermined time (first process gas supply). When the wafers 200 are exposed to the atmosphere of the first process gas, the valves 513, 523 and 533 are opened to supply the inert gas into the process chamber 201 in order to prevent the first process gas from entering the nozzles 410, 420 and 430. When a predetermined time has elapsed since the valves 313 and 323 are opened, the valves 313 and 323 are closed.

In the present specification, an operation of supplying the first process gas stored in the tanks 315 and 325 to the process chamber 201 (or to the wafers 200 in the process chamber 201) may also be referred to as a “flash supply operation”. Further, an operation of storing the first process gas in the tanks 315 and 325 and the operation of supplying the first process gas stored in the tanks 315 and 325 to the process chamber 201 may also be collectively referred to as the “flash supply operation”.

In the flash supply operation, by increasing a pressure of the first process gas stored in the tanks 315 and 325, it is possible to increase a pressure difference between the tank 315 and the process chamber 201 and a pressure difference between the tank 325 and the process chamber 201. Thereby, it is possible to increase a flow velocity of the first process gas supplied into the process chamber 201 through the gas supply ports 411 and a flow velocity of the first process gas supplied into the process chamber 201 through the gas supply ports 421. Each of the flow velocity of the first process gas supplied into the process chamber 201 through the gas supply ports 411 and the flow velocity of the first process gas supplied into the process chamber 201 through the gas supply ports 421 is set such that the first process gas passes through the nozzles 410 and 420 in a very short time without staying in the nozzles 410 and 420 and diffuses on the wafers 200 at once. As a result, it is possible for the first process gas to diffuse efficiently throughout an entirety of the process chamber 201.

The pressure difference between the tank 315 and the process chamber 201 and the pressure difference between the tank 325 and the process chamber 201 are set such that, for example, the flow velocity of the first process gas supplied through the gas supply ports 421 into the process chamber 201 is 0.8 times or more and 1.2 times or less than the flow velocity of the first process gas supplied through the gas supply ports 411 into the process chamber 201.

In the present step, for example, a temperature of the heater 207 is set to a temperature within a range from 350° C. to 650° C. For example, each of flow rates of the inert gas controlled by the MFCs 512, 522 and 532 is set to a flow rate within a range from 300 sccm to 10,000 sccm. For example, a time duration of confining the first process gas in the process chamber 201 is set to a time duration within a range from 1 second to 30 seconds.

By supplying the first process gas to the wafers 200 in accordance with the conditions described above, it is possible to form a first layer on the wafer 200 (that is, on a base film of a surface of the wafer 200).

As the inert gas, for example, nitrogen (N₂) gas or a rare gas such as argon (Ar) gas, helium (He) gas, neon (Ne) gas and xenon (Xe) gas may be used. One or more of the gases exemplified above may be used as the inert gas. The same also applies to each step described below.

Alternatively, the valves 313 and 323 may be opened while the APC valve 243 is opened so as not to close the exhauster. That is, the flash supply operation may be performed while the inner atmosphere of the process chamber 201 is continuously exhausted. In such a case, since the flow velocity of the first process gas within the process chamber 201 further increases, it is possible for the first process gas to diffuse easily and efficiently throughout the entirety of the process chamber 201.

### <Temperature Adjusting Step: S313>

After the supply step S312, the temperatures of the tanks 315 and 325 are adjusted. For example, the temperature adjusting step S313 is started when the valves 313 and 323 are closed and the supply of the first process gas from the tanks 315 and 325 is terminated. For example, the temperature adjusting step S313 is ended when the valves 314 and 324 are opened and a filling of the first process gas into the tanks 315 and 325 is started. In other words, the temperature adjusting step S313 is started at the same time as a termination of the supply step S312, and is ended at the same time as a start of the storage step S311. In the temperature adjusting step S313, for example, the tanks 315 and 325 are heated by the tank heaters 316 and 326 serving as the temperature regulator. The temperature adjusting step S313 will be described later in detail.

### <Purge Gas Supply Step: S32>

After the first layer is formed on the wafer 200, the valves 313 and 323 are closed. Then, the APC valve 243 is opened to open the exhauster, and the inner atmosphere of the process chamber 201 is vacuum-exhausted (residual gas removing step). When the inner atmosphere of the process chamber 201 is exhausted, the valves 513, 523 and 533 are opened to supply the inert gas through the gas supply pipes 510, 520 and 530 in order to purge the inner atmosphere of the process chamber 201 (purging step).

### <Second Process Gas Supply Step: S33>

After the purge gas supply step S32 is completed, with the valve 632 closed, the valve 333 is opened to supply the second process gas into the gas supply pipe 330. The second process gas whose flow rate is adjusted by the MFC 332 is supplied into the buffer chamber 433 through the gas supply ports 431. When the second process gas is supplied, by applying the high frequency power between the pair of rod-shaped electrodes, the second process gas supplied into the buffer chamber 433 is excited by a plasma (that is, excited into a plasma state) and supplied into the process chamber 201 through the gas supply ports 435, and is exhausted through the exhaust pipe 231. In the present step, the second process gas activated by the plasma is supplied to the wafer 200. In the present step, at least the valves 513 and 523 are opened to supply the inert gas into the process chamber 201 in order to prevent the second process gas from entering the nozzles 410 and 420.

In the present step, for example, the inner pressure of the process chamber 201 is set to a pressure within a range from 10 Pa to 100 Pa. By using the plasma, it is possible to activate the second process gas even when the inner pressure of the process chamber 201 is set within a relatively low pressure range described above. For example, a partial pressure of the second process gas in the process chamber 201 is set to a pressure within a range from 6 Pa to 100 Pa. For example, the flow rate of the second process gas supplied into the process chamber 201 is set to a flow rate within a range from 10 sccm to 10,000 sccm. For example, a time duration (supply time) of supplying the second process gas is set to a time duration within a range from 1 second to 120 seconds. For example, a magnitude of the high frequency power applied between the pair of rod-shaped electrodes is set to a value within a range from 50 W to 1,000 W. Other processing conditions are set to be substantially the same as the processing conditions in the first process gas supply step S31.

By supplying the second process gas excited into the plasma state to the wafer 200 in accordance with the conditions described above, a modification process is performed on the first layer formed on the surface of the wafer 200. Thereby, the first layer is modified into a second layer.

Alternatively, in the second process gas supply step S33, the first layer may be modified into the second layer by supplying the second process gas to the wafer 200 without exciting the second process gas into the plasma state. In such a case, the matcher 271, the high frequency power supply 270 and the pair of rod-shaped electrodes may not be provided. Further, the buffer chamber wall 434 may not be provided.

### <Purge Gas Supply Step: S34>

After the first layer is modified into the second layer, the valve 333 is closed to stop a supply of the second process gas into the process chamber 201 through the buffer chamber 433. In addition, an application of the high frequency power between the pair of rod-shaped electrodes is stopped. Then, the APC valve 243 is opened to open the exhauster, and the inner atmosphere of the process chamber 201 is vacuum-exhausted (residual gas removing step). When the inner atmosphere of the process chamber 201 is exhausted, the valves 513, 523 and 533 are opened to supply the inert gas through the gas supply pipes 510, 520 and 530 in order to purge the inner atmosphere of the process chamber 201 (purging step).

### <Performing a Predetermined Number of Times>

By performing a cycle wherein the first process gas supply step S31, the purge gas supply step S32, the second process gas supply step S33 and the purge gas supply step S34 are performed non-simultaneously in this order a predetermined number of times (n times, wherein n is an integer equal to or greater than 1), it is possible to form a film of a desired thickness and a desired composition on the wafer 200. It is preferable that the cycle is repeatedly performed a plurality of times. That is, it is preferable that the cycle is repeatedly performed until a thickness of the film formed by stacking the second layer by performing the cycle a plurality of times reaches the desired thickness under the conditions that the second layer formed in each cycle is thinner than the desired thickness. The film containing an element derived from the first process gas and an element derived from the second process gas may be formed.

For example, the storage step S311 and the temperature adjusting step S313 may be performed while any one of the purge gas supply step S32, the second process gas supply step S33 and the purge gas supply step S34 is being performed.

### <Returning to Atmospheric Pressure Step: S4>

After the film is formed on the wafer 200, the inert gas is supplied into the process chamber 201, and then is exhausted through the exhaust pipe 231. The inert gas serves as a purge gas. Thereby, the inner atmosphere of the process chamber 201 is purged with the inert gas, and the gas remaining in the process chamber 201 or reaction by-products remaining in the process chamber 201 can be removed from the process chamber 201 (purging step). Thereafter, the inner atmosphere of the process chamber 201 is replaced with the inert gas (substitution by inert gas), and the inner pressure of the process chamber 201 is returned to the atmospheric pressure (returning to atmospheric pressure step).

### <Substrate Unloading Step: S5>

Thereafter, the seal cap 219 is lowered by the boat elevator 115 and the lower end opening of the reaction tube 203 is opened. The boat 217 with the wafers 200 (which are processed) charged therein is transferred (unloaded) out of the reaction tube 203 (boat unloading step). After the boat 217 is unloaded out of the reaction tube 203, the wafers 200 (which are processed) are transferred (discharged) out of the boat 217 (wafer discharging step).

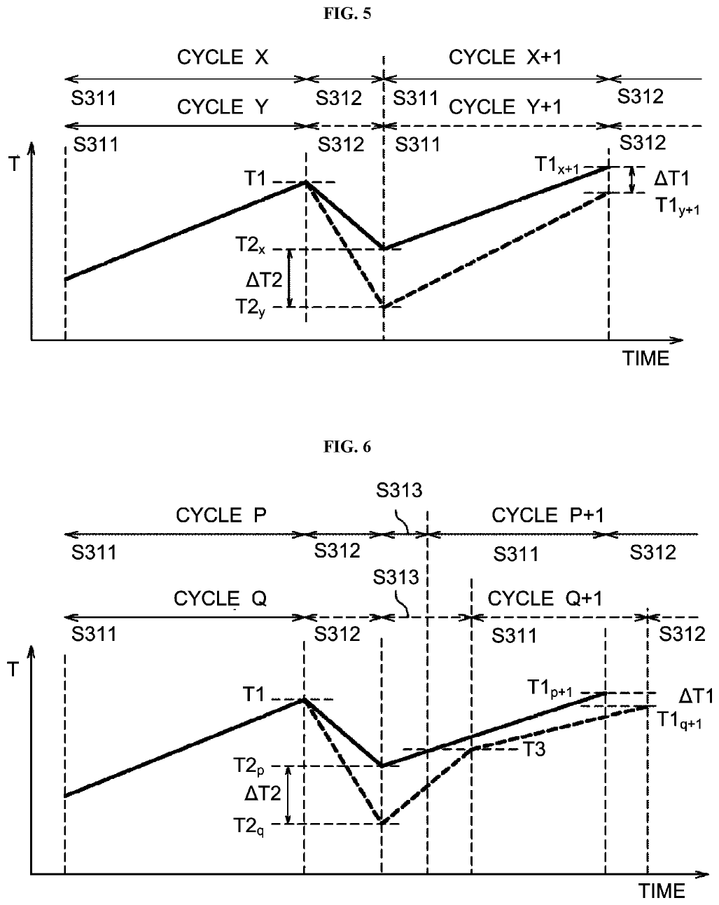

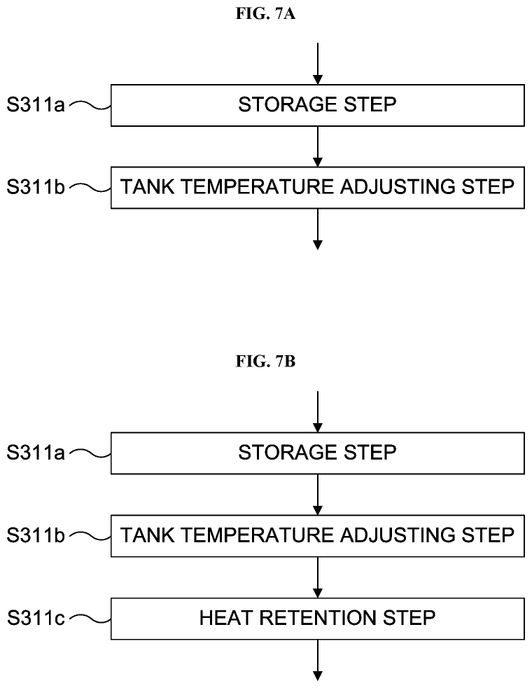

The first process gas supply step S31 will be described in detail with reference to FIGS. 5 and 6. Although the first process gas supply step S31 will be described below based on the tank 315, the same also applies to the tank 325.

When a volume of a gaseous substance increases (that is, when the gaseous substance expands) under conditions where there is no heat exchange with the outside, a temperature of the gaseous substance decreases. Further, the same may also apply for another gaseous substance that undergoes a process under conditions where the heat exchange with the outside is considered to be small, that is, a process close to an adiabatic expansion. In the present specification, such a phenomenon including the process close to the adiabatic expansion may also be expressed as an “adiabatic expansion of a gaseous substance” or “a gaseous substance expands adiabatically”. Further, when the gaseous substance expands adiabatically, a temperature of a component existing around the gaseous substance may also decrease at the same time. In the present specification, such a phenomenon in which at least one among the temperature of the gaseous substance and the temperature of the component existing around the gaseous substance decreases when the gaseous substance expands adiabatically may also be expressed as a “temperature decrease due to an adiabatic expansion”.

In the flash supply operation, the first process gas stored in the tank 315 expands in a short time, and during the time, the heat exchange between the first process gas and the outside can be considered to be small. That is, in the flash supply operation, the first process gas stored in the tank 315 is supplied to the process chamber 201 while being expanded in the process close to the adiabatic expansion. Therefore, after the flash supply operation, the temperature of the first process gas in the tank 315 or the process chamber 201 and a temperature of the first process gas supplier including the tank 315 may decrease.

In the present embodiments, when a cycle including the flash supply operation is performed a plurality of times, a magnitude of a temperature decrease due to the adiabatic expansion of the first process gas may differ between executions of the cycle. Accordingly, a temperature of the tank 315 after the flash supply operation (hereinafter, also referred to as a “second temperature”) between the executions of the cycle and the temperature of the tank 315 at a start of the flash supply operation in each execution of the cycle (hereinafter, also referred to as a “first temperature”) may be changed. Thus, a variation in the temperature of the tank 315 may occur. For example, factors that cause the magnitude of the temperature decrease due to the adiabatic expansion of the first process gas to increase or decrease may include one or more of the following changing for each execution of the cycle.
(a) A pressure and/or a temperature of a route connecting the tank 315 and the process chamber 201;
(b) The inner pressure and/or the inner temperature of the process chamber 201;
(c) An amount of the gas exhausted from the process chamber 201 per unit time; and
(d) An inner pressure and/or an inner temperature of the exhaust pipe 231.

Hereinafter, the variation in the first temperature and a variation in the second temperature between executions of a cycle of a comparative example will be described with reference to FIG. 5. In the comparative example, the temperature adjusting step S313 is not provided (performed) between the termination of the supply step S312 and the start of the storage step S311 of a subsequent execution of the cycle. According to the comparative example, the film forming process S3 is performed by performing the cycle of the comparative example a plurality of times. FIG. 5 is a diagram schematically illustrating an example in which the second temperature varies between an X^{th} execution of the cycle (“CYCLE X” in FIG. 5) and a Y^{th} execution of the cycle (“CYCLE Y” in FIG. 5) where the first temperature is the same between the X^{th} execution of the cycle and the Y^{th} execution of the cycle. A vertical axis of a graph shown in FIG. 5 represents a temperature (T) of the tank 315, and a horizontal axis represents the time. The temperature of the tank 315 for the Y^{th} execution of the cycle and the temperature of the tank 315 for a (Y+1)^{th} execution of the cycle (“CYCLE Y+1” in FIG. 5), which is subsequent to the Y^{th} execution of the cycle, are shown by a dashed line. As described above, the cycle of the comparative example includes the storage step S311 and the supply step S312, and a period (time duration) of the storage step S311 is the same in each execution of the cycle, and a period (time duration) of the supply step S312 is the same in each execution of the cycle. Further, in each execution of the cycle, it is assumed that the output of the tank heater 316 is feedback-controlled with respect to the temperature of the tank 315 such that the temperature of the tank 315 approaches a predetermined temperature T1.

In the supply step S312 of the X^{th} execution of the cycle, the temperature of the tank 315 decreases by the temperature decrease due to the adiabatic expansion of the first process gas. The second temperature, which is the temperature of the tank 315 at the end of the supply step S312 of the X^{th} execution of the cycle, is a temperature T2ₓ. In the comparative example, the temperature T2ₓ is changed (set) to be lower than the temperature T1.

In the storage step S311 of an (X+1)^{th} execution of the cycle (“CYCLE X+1” in FIG. 5), the temperature of the tank 315 increases from the temperature T2ₓ due to the heating by the tank heaters 316 and 326 and the like, for example. The first temperature, which is the temperature of the tank 315 at an end of the storage step S311 (at the start of the supply step S312) of the (X+1)^{th} execution of the cycle, is a temperature T1ₓ₊₁.

In the supply step S312 of the Y^{th} execution of the cycle, the temperature of the tank 315 decreases by the temperature decrease due to the adiabatic expansion of the first process gas. The second temperature, which is the temperature of the tank 315 at the end of the supply step S312 of the Y^{th} execution of the cycle, is a temperature T2_{y}. In the comparative example, the temperature T2_{y} is changed (set) to be lower than the temperature T1, and the temperature T2_{y} is changed (set) to be lower than the temperature T2ₓ. When ΔT2 represents the variation in the second temperature, the variation ΔT2 is obtained by subtracting the temperature T2_{y} from the temperature T2ₓ.

In the storage step S311 of the (Y+1)th execution of the cycle, the temperature of the tank 315 increases from the temperature T2_{y} due to the heating by the tank heater 316 and the like, for example. The first temperature, which is the temperature of the tank 315 at an end of the storage step S311 (at the start of the supply step S312) of the (Y+1)th execution of the cycle, is a temperature T1_{y+1}. When ΔT1 represents the variation in the first temperature, the variation ΔT1 is obtained by subtracting the temperature T1_{y+1} from the temperature T1ₓ₊₁.

When each of the storage step S311 of the (X+1)^{th} execution of the cycle and the storage step S311 of the (Y+1)^{th} execution of the cycle is performed for a sufficiently long time, by a feedback control of the output of the tank heater 316, the temperature T1ₓ₊₁ and the temperature T1_{y+1} approach the temperature T1. As a result, since a difference between the temperature T1ₓ₊₁ and the temperature T1_{y+1} becomes smaller, the variation ΔT1 eventually is changed (set) to zero (0).

However, as the semiconductor device is miniaturized and a complexity of the semiconductor device increases, there are great demands for improving a step coverage and to shorten a process time. Therefore, it is expected that the variation in the first temperature and the variation in the second temperature will also increase. For example, consider a case where the step coverage is improved by increasing the amount of the first process gas supplied in the supply step S312 in accordance with an increase in a surface area of the wafer 200. In such a case, the temperature drop in the tank 315 due to the adiabatic expansion in the supply step S312 increases, and the variation ΔT2 also increases accordingly. Therefore, it is expected that and the variation ΔT1 will not be sufficiently eliminated by the feedback control of the output of the tank heater 316 in the storage step S311. Further, for example, consider a case where the time for performing the storage step S311 is shortened in order to improve the productivity. In such a case, it is expected that the variation ΔT1 will not be sufficiently eliminated by the feedback control of the output of the tank heater 316 or the like.

Subsequently, the variation in the first temperature and the variation in the second temperature between the executions of the cycle of the present embodiments will be described with reference to FIG. 6. In the present embodiments, the temperature adjusting step S313 is provided (performed) between the termination of the supply step S312 and the start of the storage step S311 of a subsequent execution of the cycle. According to the present embodiments, the film forming process S3 is performed by performing the cycle of the present embodiments a plurality of times. FIG. 6 is a diagram schematically illustrating an example in which the second temperature varies between a P^{th} execution of the cycle (“CYCLE P” in FIG. 6) and a Q^{th} execution of the cycle (“CYCLE Q” in FIG. 6) where the first temperature is the same. A vertical axis of a graph shown in FIG. 6 represents the temperature (T) of the tank 315, and a horizontal axis represents the time. The temperature of the tank 315 for the Q^{th} execution of the cycle and the temperature of the tank 315 for a (Q+1)th execution of the cycle (“CYCLE Q+1” in FIG. 6), which is subsequent to the Q^{th} execution of the cycle, are shown by a dashed line. As described above, the cycle of the present embodiments includes the storage step S311, the supply step S312 and the temperature adjusting step S313. In the example shown in FIG. 6, the temperature adjusting step S313 is performed from the time when the supply step S312 is terminated until the time when the storage step S311 is started. The period (time duration) of the storage step S311 is the same in each execution of the cycle, and the period (time duration) of the supply step S312 is the same in each execution of the cycle.

In the storage step S311 of the P^{th} execution of the cycle, the temperature of the tank 315 increases due to the heating by the tank heater 316 and the like, for example. The first temperature, which is the temperature of the tank 315 at the end of the storage step S311 (at the start of the supply step S312) of the P^{th} execution of the cycle, is the temperature T1.

In the supply step S312 of the P^{th} execution of the cycle, the temperature of the tank 315 decreases by the temperature decrease due to the adiabatic expansion of the first process gas. The second temperature, which is the temperature of the tank 315 at the end of the supply step S312 of the P^{th} execution of the cycle, is a temperature T2ₚ. In the example shown in FIG. 6, the temperature T2ₚ is changed (set) to be lower than the temperature T1.

In the temperature adjusting step S313 of the P^{th} execution of the cycle, the temperature of the tank 315 changes (increases) to a third temperature T3 higher than the second temperature T2ₚ due to the heating by the tank heater 316, for example.

After the temperatures of the tanks 315 and 325 reach the third temperature, the storage step S311 of a (P+1)th execution of the cycle (“CYCLE P+1” in FIG. 6) is started. In the storage step S311 of the (P+1)th execution of the cycle, the temperature of the tank 315 increases from the third temperature T3 due to the heating by the tank heater 316 and the like, for example. The first temperature, which is the temperature of the tank 315 at the end of the storage step S311 (at the start of the supply step S312) of the (P+1)th execution of the cycle, is a temperature T1ₚ₊₁.

In the storage step S311 of the Q^{th} execution of the cycle, the temperature of the tank 315 increases due to the heating by the tank heater 316 and the like, for example. The first temperature, which is the temperature of the tank 315 at the end of the storage step S311 (at the start of the supply step S312) of the Q^{th} execution of the cycle, is the temperature T1.

In the supply step S312 of the Q^{th} execution of the cycle, the temperature of the tank 315 decreases by the temperature decrease due to the adiabatic expansion of the first process gas. The second temperature, which is the temperature of the tank 315 at the end of the supply step S312 of the Q^{th} execution of the cycle, is a temperature T2_{q}. In the example shown in FIG. 6, the temperature T2_{q} is changed (set) to be lower than the temperature T1, and the temperature T2_{q} is changed (set) to be lower than the temperature T2ₚ. When ΔT2 represents the variation in the second temperature, the variation ΔT2 is obtained by subtracting the temperature T2_{q} from the temperature T2ₚ.

In the temperature adjusting step S313 of the Q^{th} execution of the cycle, the temperature of the tank 315 changes (increases) to the third temperature T3 higher than the second temperature T2_{q} due to the heating by the tank heater 316, for example. In the example shown in FIG. 6, the third temperature in the Q^{th} execution of the cycle and the third temperature in the P^{th} execution of the cycle are the same temperature.

After the temperature of the tank 315 reaches the third temperature, the storage step S311 of the (Q+1)^{th} execution of the cycle is started. In the storage step S311 of the (Q+1)^{th} execution of the cycle, the temperature of the tank 315 increases from the third temperature T3 due to the heating by the tank heater 316 and the like, for example. The first temperature, which is the temperature of the tank 315 at the end of the storage step S311 (at the start of the supply step S312) of the (Q+1)^{th} execution of the cycle, is a temperature T1_{q+1}. In the example shown in FIG. 6, the time of the temperature adjusting step S313 of the (Q+1)^{th} execution of the cycle is the same as the time of the temperature adjusting step S313 of the (P+1)^{th} execution of the cycle. Further, the temperature T1_{q+1} is changed (set) to be lower than the temperature T1ₚ₊₁. When the ΔT1 represents the variation in the first temperature, the variation ΔT1 is obtained by subtracting the temperature T1_{q+1} from the temperature T1ₚ₊₁.

In the comparative example, the storage step S311 of the (X+1)^{th} execution of the cycle and the storage step S311 of the (Y+1)^{th} execution of the cycle are started immediately after the end of the supply step S312 of the (X+1)^{th} execution of the cycle and the end of the storage step S311 of the (Y+1)^{th} execution of the cycle, respectively. Therefore, the storage step S311 of the (X+1)^{th} execution of the cycle and the storage step S311 of the (Y+1)^{th} execution of the cycle are started in a state where there is a difference in the temperature of the tank 315. On the other hand, in the example shown in FIG. 6, after the temperature of the tank 315 is changed (set) to the third temperature in the temperature adjusting step S313 of the P^{th} execution of the cycle of the present embodiments and the temperature adjusting step S313 of the Q^{th} execution of the cycle of the present embodiments, the storage step S311 of the (P+1)^{th} execution of the cycle of the present embodiments and the storage step S311 of the (Q+1)^{th} execution of the cycle of the present embodiments are started. That is, the temperature of the tank 315 at the start of the storage step S311 of the (P+1)^{th} execution of the cycle of the present embodiments and the temperature of the tank 315 at the start of the storage step S311 of the (Q+1)^{th} execution of the cycle of the present embodiments are changed (set) to the third temperature T3. Therefore, by performing the temperature adjusting step S313, it is possible to reduce or to eliminate the variation in the first temperature (ΔT1) in a short time. Further, by performing the temperature adjusting step S313, even when the variation in the second temperature (ΔT2) increases, it is possible to reduce or to eliminate the variation in the first temperature (ΔT1). In other words, it is possible to start the supply step S312 after the first temperature is kept within a predetermined temperature range while the cycle of the present embodiments is performed the plurality of times. In the present embodiments, for example, the predetermined temperature range may refer to a temperature range equal to or greater than a predetermined minimum temperature and equal to or less than a predetermined maximum temperature. For example, the predetermined temperature range is set such that a difference between the predetermined minimum temperature and the predetermined maximum temperature is within 5° C., preferably within 3° C., and more preferably within 1° C.

As described above, at a timing when the temperature adjusting step S313 is performed in each execution of the cycle such that the temperature of the tank 315 reaches a specific level of the third temperature that is common to the plurality of executions of the cycle, the storage step S311 of the subsequent execution of the cycle of the present embodiments is started. However, the technique of the present disclosure is not limited thereto. In the temperature adjusting step S313, the temperature of the tank 315 may not be maintained at the third temperature, and it is sufficient that the temperature of the tank 315 at least temporarily reaches the third temperature. In other words, in each execution of the cycle of the present embodiments, the storage step S311 may be started after the temperature of the tank 315 is changed from the second temperature to the third temperature. For example, in each execution of the cycle of the present embodiments, the storage step S311 may be started after the temperature of the tank 315 reaches the third temperature or higher. Alternatively, in each execution of the cycle of the present embodiments, the storage step S311 may be started after the temperature of the tank 315 changes lower than the third temperature. Even in such a case, it is possible to obtain substantially the same effect because the variations in the temperatures of the tanks 315 and 325 at the start of the storage step S311 between the executions of the cycle of the present embodiments can be reduced as compared with a case where the temperature adjusting step S313 is not performed.

Further, in the temperature adjusting step S313, the third temperature may be kept within a predetermined temperature range while the cycle of the present embodiments is performed the plurality of times. For example, a temperature range equal to or greater than a predetermined minimum temperature and equal to or less than a predetermined maximum temperature may be set as the predetermined temperature range, and the storage step S311 may be started when the temperature of the tank 315 comes into the predetermined temperature range. Even in such a case, it is possible to obtain substantially the same effect because the variations in the temperatures of the tanks 315 and 325 at the start of the storage step S311 between the executions of the cycle of the present embodiments can be reduced as compared with a case where the temperature adjusting step S313 is not performed. In the present embodiments, as the difference between the predetermined minimum temperature and the predetermined maximum temperature is decreased, the temperatures of the tanks 315 and 325 at the start of the storage step S311 deviate less between the executions of the cycle of the present embodiments. Therefore, it is possible to reduce the variation in the first temperature. For example, it is preferable to set the predetermined temperature range such that the difference between the predetermined minimum temperature and the predetermined maximum temperature is becomes 10° C. or less. Further, it is more preferable to set the predetermined temperature range such that the difference between the predetermined minimum temperature and the predetermined maximum temperature becomes 5° C. or less. Further, it is more preferable to set the predetermined temperature range such that the difference between the predetermined minimum temperature and the predetermined maximum temperature becomes 3° C. or less.

The third temperature may be set to be equal to or higher than the second temperature. Further, the predetermined temperature range of the third temperature may be set such that the predetermined minimum temperature is equal to or higher than the second temperature. In order to supply the first process gas whose variation in the temperature is small between the executions of the cycle of the present embodiments, it is preferable that the tank 315 whose temperature becomes low due to the adiabatic expansion is heated in each execution of the cycle of the present embodiments. When the third temperature is set to a temperature equal to or higher than the second temperature, it is possible to shorten the time for the temperature of the tank 315 to reach the same temperature as in the supply step S312 in a previous execution of the cycle of the present embodiments. Therefore, it becomes easier to supply the first process gas at the same temperature to the wafer 200 in each execution of the cycle of the present embodiments while suppressing an increase in the process time.

The third temperature may be set to be lower than the second temperature. Further, the predetermined temperature range of the third temperature may be changed (set) such that the predetermined maximum temperature is lower than the second temperature. The tanks 315 and 325 are cooled by reducing the outputs of the tank heaters 316 and 326 or by setting the outputs of the tank heaters 316 and 326 to zero (0). Therefore, the third temperature may be set to be lower than the second temperature. Even in such a case, it is possible to reduce at least the variation in the first temperature.

The storage step S311 may be started when the temperature of the tank 315 reaches the third temperature in the temperature adjusting step S313. Thereby, the temperature of the tank 315 at the time when the storage of the first process gas is started can be uniformized between the executions of the cycle of the present embodiments. Thereby, it is possible to further reduce the variation in the first temperature.

The storage step S311 may be started after a predetermined time has elapsed since the temperature of the tank 315 is changed (set) to the third temperature in the temperature adjusting step S313. Thereby, it is possible to further suppress the variation in the temperature of the tank 315 after the supply step S312 of each execution of the cycle of the present embodiments. Therefore, it is possible to suppress a variation within the processing between the executions of the cycle of the present embodiments.

For example, when starting the supply step S312 at the timing when the temperature of the tank 315 reaches the third temperature in the temperature adjusting step S313, the supply step S312 may be started when the thermocouple 319 detects that the temperature of the tank 315 reaches the third temperature. Further, for example, an elapsed time (time t) from a time when the temperature adjusting step S313 is started until a time when the temperature of the tank 315 reaches the third temperature is obtained in advance by a predetermined method. Then, the supply step S312 may be started at the time when the temperature adjusting step S313 is started or may be started when the time t has elapsed. In the present embodiments, the predetermined method may include a method of calculating and/or a method of predicting the time t, based on data obtained from results of evaluations performed using the substrate processing apparatus or the components of the substrate processing apparatus, at least before the substrate processing or during the substrate processing, for example. Further, for example, the predetermined method may include a method of calculating and/or a method of predicting the time t based on results of a numerical calculation including a computer simulation.

The temperature adjusting step S313 is performed after the supply step S312, that is, before the storage step S311. Since a heat capacity of the first process gas in the tank 315 before the storage step S311 is smaller than that of the first process gas in the tank 315 after the storage step S311, an amount of the heat for a temperature change is small. Therefore, it is possible to suppress an influence of the variations in the temperatures of the tanks 315 and 325 in a shorter time as compared with a case where the temperature of the tank 315 is adjusted after the storage step S311.

In the present embodiments, a source gas described later may be used as the first process gas, and a reactive gas reacting with the source gas may be used as the second process gas. Alternatively, the reactive gas described later may be used as the first process gas, and the source gas may be used as the second process gas. That is, in the first process gas supply step S31, the source gas may be supplied in the flash supply operation or the reactive gas may be supplied in the flash supply operation.

As the source gas, for example, a metal element-containing gas may be used. As the metal element-containing gas, for example, a gas containing an element such as tungsten (W), titanium (Ti), tantalum (Ta), cobalt (Co), yttrium (Y), ruthenium (Ru), aluminum (Al), molybdenum (Mo), niobium (Nb), hafnium (Hf), zirconium (Zr) and silicon (Si) may be used. Further, as the metal element-containing gas, a gas obtained by vaporizing a substance in a liquid state or a solid state at a room temperature and a normal pressure may be used.

As the metal element-containing gas, for example, a gas containing at least one among tungsten hexafluoride (WF₆), tungsten hexachloride (WCl₆), titanium tetrafluoride (TiF₄), titanium tetrachloride (TiCl₄), tantalum pentafluoride (TaFs), tantalum pentachloride (TaCls), cobalt difluoride (CoF₂), cobalt dichloride (CoCl₂), yttrium trifluoride (YF₃), yttrium trichloride (YCl₃), ruthenium trifluoride (RuF₃), ruthenium trichloride (RuCl₃), bis (ethylcyclopentadienyl) ruthenium (Ru (EtCp)₂), bis (cyclopentadienyl) ruthenium (Ru(Cp)₂), aluminum trifluoride (AlF₃), aluminum trichloride (AlCl₃), molybdenum pentafluoride (MoFs), molybdenum pentachloride (MoCl₅), molybdenum dichloride dioxide (MoO₂Cl₂), molybdenum tetrachloride oxide (MoOCl₄) niobium trifluoride (NbF₃), niobium trichloride (NbCl₃), manganese difluoride (MnF₂), manganese dichloride (MnCl₂), nickel difluoride (NiF₂), nickel dichloride (NiCl₂), tetrakis (ethylmethylamino) zirconium (Zr[N(Me)Cp]₄), tetrakis (diethylamino) zirconium (Zr[N(Et)₂]₄), (dimethylamino) zirconium (Zr[N(Me)₂]₄), tris (dimethylaminocyclopentadienyl) tetrakis zirconium ((Cp)Zr[N(Me)₂]₃), tetrakis (ethylmethylamino) hafnium (Hf[N(Me)Et]₄), tetrakis (diethylamino) hafnium (Hf[N(Et)₂]₄), tetrakis (dimethylamino) hafnium (Hf[N(Me)₂]₄), tris (dimethyl aminocyclopentadienyl) hafnium ((Cp)Hf[N(Me)₂]₃) and the like may be used.

Further, as a silicon-containing gas serving as the metal element-containing gas, for example, a chlorosilane-based gas may be used. As the chlorosilane-based gas, for example, a gas containing at least one among dichlorosilane (SiH₂Cl₂), dichlorodisilane (Si₂H₄Cl₂), tetrachlorodisilane (Si₂H₂Cl₄), hexachlorodisilane (Si₂Cl₆) and the like may be used. Further, as a silicon-containing gas serving as the metal element-containing gas, for example, a silane-based gas may be used. As the silane-based gas, for example, a gas containing at least one among monosilane (SiH₄), disilane (Si₂H₆), trisilane (Si₃H₈), tetrasilane (Si₄H₁₀) and the like may be used.

As the reaction gas, for example, a reducing gas, a nitriding gas or an oxidizing gas may be used. In the present embodiments, for example, when one of the first process gas and the second process gas is the metal element-containing gas and the other one of the first process gas and the second process gas is the reducing gas, a conductive metal film mainly constituted by a single metal element can be formed on the wafer 200. For example, when one of the first process gas and the second process gas is the metal element-containing gas and the other one of the first process gas and the second process gas is the oxidizing gas, a metal oxide film can be formed on the wafer 200. Further, for example, when one of the first process gas and the second process gas is the metal element-containing gas and the other one of the first process gas and the second process gas is the nitriding gas, a metal nitride film can be formed on the wafer 200.

As the reducing gas, for example, a gas containing at least one among hydrogen (H₂) gas, deuterium (D₂) gas, borane (BH₃) gas, diborane (B₂H₆) gas, carbon monoxide (CO) gas, ammonia (NH₃) gas, monosilane (SiH₄) gas, disilane (Si₂H₆) gas, trisilane (Si₃H₈) gas, monogermane (GeH₄) gas, digermane (Ge₂H₆) and the like may be used. As the reactive gas, for example, the oxidizing gas which is an oxygen-containing gas may be used. As the oxidizing gas, for example, a gas containing at least one among oxygen (O₂), ozone (O₃), water vapor (H₂O), a gaseous mixture of the H₂ and the O₂, hydrogen peroxide (H₂O₂), nitrous oxide (N₂₀) and the like may be used. As the nitriding gas, for example, a hydrogen nitride-based gas such as the ammonia (NH₃) gas, diazene (N₂H₂) gas, hydrazine (N₂H₄) gas and N₃H₈ gas may be used. As the reactive gas, for example, one or more of the gases exemplified above may be used.

As the first process gas, for example, the source gas or the reactive gas resistible to a self-decomposition reaction within a space (that is, the process chamber 201) where the wafer 200 is accommodated may be used. For example, the reducing gas such as the H2 serving as the reactive gas may be considered as a gas that does not cause the self-decomposition reaction within the process chamber 201. A reactivity of the gas that does not cause the self-decomposition reaction tends to be low with respect to the surface of the wafer 200. When such a gas is supplied as the first process gas in the flash supply operation, it is preferable to increase the amount of the first process gas stored in each of the tanks 315 and 325 (that is, it is preferable to increase a charge pressure), and it is preferable to increase a partial pressure of the first process gas in the process chamber 201 in the supply step S312. Thereby, since the surface of the wafer 200 and the first process gas can sufficiently react with each other, it is possible to improve a film forming rate. However, when the charge pressure increases, the temperature of the tank 315 tends to decrease due to the adiabatic expansion of the first process gas, and the variations in the first temperature and second temperature between the executions of the cycle of the present embodiments tend to increase. Even when a process gas such as the first process gas resistible to the self-decomposition reaction is supplied in the flash supply operation at a relatively high charge pressure, by using the technique of the present disclosure, it is possible to reduce the variation within the processing between the executions of the cycle of the present embodiments.

For example, when forming the metal film on the wafer 200 using the metal element-containing gas as the first process gas and the reducing gas as the second process gas, a conductive film (metal film) may adhere to an inside of the process chamber 201. Thereby, an unintended discharge is likely to occur when the reducing gas is excited by the plasma. For example, consider a case where the metal film is formed on the wafer 200 using the reducing gas as the first process gas and the metal element-containing gas as the second process gas. In such a case, a partial pressure of the reducing gas in the process chamber 201 can be increased by supplying the reducing gas in the flash supply operation. Thereby, it is possible to improve the reactivity of the reducing gas with respect to the surface of the wafer 200 without using a plasma excitation of the reducing gas.

As the first process gas, for example, the source gas or the reactive gas susceptible to the self-decomposition reaction within the space (that is, the process chamber 201) where the wafer 200 is accommodated may be used. For example, the silicon-containing gas such as the SiH₂Cl₂, the Si₂H₄C₁₂, the Si₂H₂Cl₄ and the Si₂Cl₆ serving as the source gas may be considered as a gas susceptible to the self-decomposition reaction within the process chamber 201. In such a gas, a susceptibility of the self-decomposition reaction may change depending on a temperature thereof. That is, the variations in the temperatures of the tanks 315 and 325 between the executions of the cycle of the present embodiments tend to cause the variation within a processing result between the executions of the cycle of the present embodiments. Even in such a case, since the variation in the temperature of the tank 315 between the executions of the cycle of the present embodiments can be reduced, it is possible to stabilize a temperature of the process gas susceptible to the self-decomposition reaction. Therefore, it is possible to reduce the variation within the processing between the executions of the cycle of the present embodiments.

In the flash supply operation, as the amount of the first process gas stored in the tank 315 and the amount of the first process gas supplied to the wafer 200 increase, it becomes easier to supply the first process gas whose amount is sufficient for the wafer 200 with a large surface area. Thereby, it becomes easier to improve the step coverage. Preferably, the amount of the first process gas supplied from the tank 315 to the wafer 200 in the supply step S312 is at least half the amount of the first process gas stored in the tank 315 in the storage step S311. However, as the amount of the first process gas supplied from the tank 315 increases relative to the amount of the first process gas stored in the tank 315, a pressure change inside the tank 315 and the variations in the first temperature and the second temperature between the executions of the cycle of the present embodiments may tend to increase. According to the technique of the present disclosure, it is possible to suppress such an influence by the effects described above. Thereby, it is possible to form the film with a sufficient step coverage while reducing the variation within the processing between the executions of the cycle of the present embodiments.

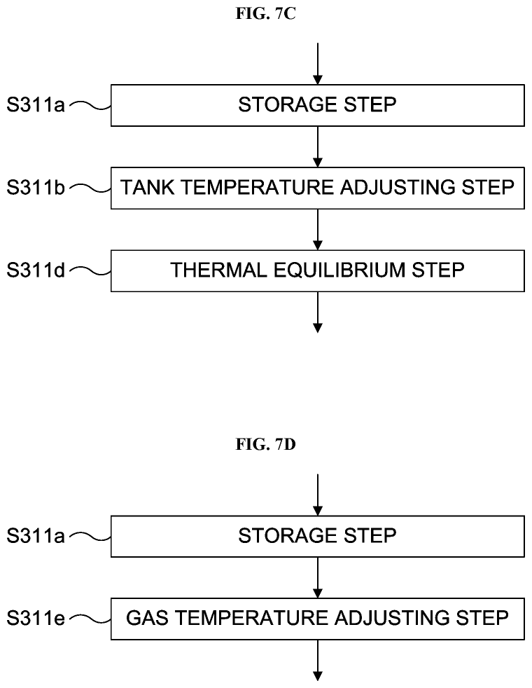

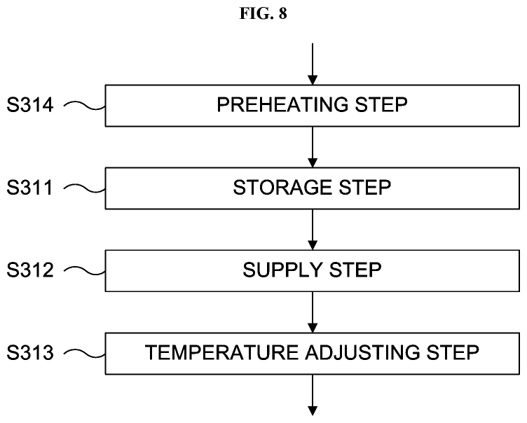

Other examples in which the variation in the first temperature is reduced will be described with reference to FIGS. 7A through 7D and FIG. 8.

Preferably, the substrate processing described above is performed such that the plurality of executions of the cycle of the present embodiments may include at least one set of two or more executions wherein the first temperature does not deviate between the two or more executions. Thereby, it is possible to further reduce the variation in the temperature of the first process gas (which is supplied to the wafer 200) between the executions of the cycle of the present embodiments. Therefore, it is also possible to suppress the variation within the processing between the executions of the cycle of the present embodiments. More preferably, in the substrate processing described above, the plurality of executions of the cycle of the present embodiments are performed such that the first temperature does not deviate between the plurality of executions of the cycle of the present embodiments. Thereby, it is possible to further suppress variation within the processing between the executions of the cycle of the present embodiments. Such an effect will be described using some specific examples.

### First Example

As shown in FIG. 7A, as the storage step S311, a storage step S311a in which the first process gas is stored in the tank 315 and a tank temperature adjusting step S311b in which the temperature of the tank 315 is set to the first temperature after the storage step S311a may be performed. In other words, in each execution of the cycle of the present embodiments, the supply step S312 is started after the storage step S311 is performed, that is, after the storage step S311a in which the first process gas is stored in the tank 315 and the tank temperature adjusting step S311b in which the temperature of the tank 315 is uniformized between the executions of the cycle of the present embodiments performed after the storage step S311a are performed. Thereby, it is possible to further suppress the variation within the processing between the executions of the cycle of the present embodiments due to the variation in the temperature of the tank 315 after the supply step S312.

### Second Example

As shown in FIG. 7B, as the storage step S311, in addition to the storage step S311a and the tank temperature adjusting step S311b shown in FIG. 7A, a heat retention step S311c in which the temperature of the tank 315 is maintained at the first temperature until a predetermined time has elapsed may be further performed. Thereby, the tank 315 and the first process gas stored in the tank 315 can be brought close to a thermal equilibrium state. Therefore, it is possible to further reduce the variation in the temperature of the first process gas (which is supplied to the wafer 200) in each execution of the cycle of the present embodiments.

### Third Example

As shown in FIG. 7C, as the storage step S311, in addition to the storage step S311a and the tank temperature adjusting step S311b shown in FIG. 7A, a thermal equilibrium step S311d in which the temperature of the first process gas stored in the tank 315 is set to the first temperature may be further performed. In the thermal equilibrium step S311d, the first process gas stored in the tank 315 and the tank 315 can be brought into the thermal equilibrium state. Thereby, it is possible to further suppress the variation within the processing between the executions of the cycle of the present embodiments. For example, when a processing of the heat retention step S311c shown in FIG. 7B is performed until the temperature of the first process gas stored in the tank 315 reaches the first temperature, it may be considered that the heat retention step S311c and the thermal equilibrium step S311d are performed in parallel.

### Fourth Example

As shown in FIG. 7D, instead of the tank temperature adjusting step S311b (shown in FIG. 7A) in which the temperature of the tank 315 is set to the first temperature, a gas temperature adjusting step S311e in which the temperature of the first process gas is changed (set) to the first temperature may be performed. For example, output conditions for the tank heater 316 capable of setting (adjusting) the temperature of the first process gas stored in the tank 315 to the first temperature are obtained in advance by a predetermined method. Then, by controlling the tank heater 316 under the output conditions, the temperature of the first process gas stored in the tank 315 may reach the first temperature without controlling the temperature of the tank 315 to the first temperature. In the present example, the predetermined method may include a method of calculating and/or a method of predicting the temperature of the first process gas stored in the tank 315, based on data obtained from results of evaluations performed using the substrate processing apparatus or the components of the substrate processing apparatus, at least before the substrate processing or during the substrate processing, for example. Further, for example, the predetermined method may include a method of calculating and/or a method of predicting the temperature of the first process gas stored in the tank 315 based on results of a numerical calculation including a computer simulation. Thereby, it is possible to further suppress the variation within the processing between the executions of the cycle of the present embodiments.

For example, the temperature of the first process gas in the tank 315 may reach the first temperature while the first process gas is being stored in the tank 315 in the storage step S311a. In such a case, it may be considered that the tank temperature adjusting step S311b and the gas temperature adjusting step S311e are performed in parallel.

For example, as shown in FIG. 8, a preheating step S314 of supplying the first process gas to the heat exchanger 318 may be performed before the storage step S311. By heating (preheating) the first process gas by the heat exchanger 318 and then storing first process gas in the tank 315, it is possible to further reduce the variation in the temperature of the first process gas (which is supplied to the wafer 200) in each execution of the cycle of the present embodiments. Further, for example, when a step of equalizing the temperature of the tank 315 and the temperature of the first process gas stored in the tank 315 between the executions of the cycle of the present embodiments is performed, such as the tank temperature adjusting step S311b and the gas temperature adjusting step S311e, it is possible to shorten the time for performing the steps.

### Other Embodiments of Present Disclosure

While the technique of the present disclosure is described in detail by way of the embodiments and the examples described above, the technique of the present disclosure is not limited thereto. The technique of the present disclosure may be modified in various ways without departing from the scope thereof.

For example, the embodiments and the examples described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments and the examples described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

Process procedures and process conditions of each process using the substrate processing apparatuses exemplified above may be substantially the same as those of the embodiments described above. Even in such a case, it is possible to obtain substantially the same effects as in the embodiments described above.

Further, the embodiments and the examples described above may be appropriately combined. Process procedures and process conditions of each combination thereof may be substantially the same as those of the embodiments described above.

According to some embodiments of the present disclosure, it is possible to suppress the variation within the substrate processing.

What is claimed is:

1. A substrate processing method comprising:
performing a cycle a plurality of times, the cycle comprising:
(a) storing a first process gas in a storage;
(b) supplying the first process gas from the storage at a first temperature to a substrate after (a) to change a temperature of the storage to a second temperature lower than the first temperature; and
(c) changing the temperature of the storage after supplying the first process gas to a third temperature after (b),
wherein (a), (b) and (c) are sequentially performed in the cycle, and
wherein the third temperature is kept within a predetermined temperature range while the cycle is performed the plurality of times.

2. The substrate processing method of claim 1, wherein the third temperature is set to be equal to or higher than the second temperature.

3. The substrate processing method of claim 1, wherein the third temperature is set to be lower than the second temperature.

4. The substrate processing method of claim 1, wherein (a) is started when the temperature of the storage reaches the third temperature in (c).

5. The substrate processing method of claim 1, wherein the first temperature of two or more executions of the cycle does not deviate therebetween.

6. The substrate processing method of claim 1, wherein the cycle is performed the plurality of times such that the first temperature does not deviate between the plurality of times of the cycle being performed.

7. The substrate processing method of claim 1, wherein (a) comprises:
(a1) storing the first process gas in the storage; and
(a2) setting the temperature of the storage to the first temperature after (a1).

8. The substrate processing method of claim 7, wherein (a) further comprises
(a3) maintaining the temperature of the storage at the first temperature until a predetermined time has elapsed after (a2).

9. The substrate processing method of claim 1, wherein (a) comprises
(a4) setting the temperature of the first process gas stored in the storage to the first temperature.

10. The substrate processing method of claim 1, wherein the cycle further comprises
(d) supplying the first process gas to a preheating structure before (a).

11. The substrate processing method of claim 1, wherein (a) is started after a predetermined time has elapsed since the temperature of the storage is set to the third temperature in (c).

12. The substrate processing method of claim 1, wherein the first process gas is resistant to a self-decomposition reaction within a space where the substrate is accommodated.

13. The substrate processing method of claim 1, wherein the first process gas is susceptible to a self-decomposition reaction within a space where the substrate is accommodated.

14. The substrate processing method of claim 1, wherein an amount of the first process gas supplied from the storage to the substrate in (b) is at least half an amount of the first process gas stored in the storage in (a).

15. The substrate processing method of claim 1, wherein the cycle further comprises
(e) supplying a second process gas to the substrate.

16. A method of manufacturing a semiconductor device, comprising the substrate processing method of claim 1.

17. A substrate processing apparatus comprising:
a process chamber in which a substrate is processed;
a storage in which a first process gas is stored;
a temperature regulator configured to control a temperature of the storage;
a gas controller configured to control a storage of the first process gas in the storage and configured to control a supply of the first process gas from the storage to the substrate; and
a controller configured to be capable of controlling the temperature regulator and the gas controller to perform a cycle a plurality of times, the cycle comprising:
(a) storing the first process gas in the storage;
(b) supplying the first process gas from the storage at a first temperature to the substrate after (a) to change the temperature of the storage to a second temperature lower than the first temperature; and
(c) changing the temperature of the storage after supplying the first process gas to a third temperature after (b),
wherein (a), (b) and (c) are sequentially performed in the cycle, and
wherein the third temperature is kept within a predetermined temperature range while the cycle is performed the plurality of times.

18. A non-transitory computer-readable recording medium storing a program that causes a substrate processing apparatus, by a computer, to perform a cycle a plurality of times, the cycle comprising:
(a) storing a first process gas in a storage;
(b) supplying the first process gas from the storage at a first temperature to a substrate after (a) to change a temperature of the storage to a second temperature lower than the first temperature; and
(c) changing the temperature of the storage after supplying the first process gas to a third temperature after (b),
wherein (a), (b) and (c) are sequentially performed in the cycle, and
wherein the third temperature is kept within a predetermined temperature range while the cycle is performed the plurality of times.
